(19) United States
(12) Patent Application Publication
(10) Pub. No.: US 2024/0153875 A1
(43) Pub. Date: May 9, 2024

(54) BACKSIDE CONTACT METAL FILL

(71) Applicant: INTERNATIONAL BUSINESS MACHINES CORPORATION, ARMONK, NY (US)

(72) Inventors: Ruilong Xie, Niskayuna, NY (US); Koichi Motoyama, Clifton Park, NY (US); Chih-Chao Yang, Glenmont, NY (US); Feng Liu, Niskayuna, NY (US)

(21) Appl. No.: 18/054,133

(22) Filed: Nov. 9, 2022

(51) Int. Cl. H01L 23/528; H01L 21/28; H01L 21/8234; H01L 21/8238; H01L 23/535; H01L 27/06; H01L 27/088; H01L 29/06; H01L 29/417; H01L 29/66; H01L 29/786

(52) U.S. Cl. CPC H01L 23/5286; H01L 21/28141; H01L 21/823475; H01L 21/823814; H01L 21/823821; H01L 23/535; H01L 27/0694; H01L 27/0886; H01L 29/0673; H01L 29/41733; H01L 29/66553; H01L 29/66795; H01L 29/78642

(57) ABSTRACT

A semiconductor device includes a first source/drain element on a first side of the semiconductor device, a second source/drain element on an opposing side of the semiconductor device, a backside contact including a first contact end on a first end of the first source/drain element and an opposing contact end in electrical communication with a backside power distribution network, a critical dimension of the first contact end is smaller than the critical dimension of the opposing contact end, and the backside contact is substantially aligned to the first source/drain element. The semiconductor device also includes and a source/drain placeholder material with a critical dimension of a middle portion of the source/drain placeholder material being larger than the critical dimension of both tend portions.

### BACKGROUND

The present disclosure generally relates to fabrication methods and resulting structures for semiconductor devices, and more particularly, to fabrication methods and resulting semiconductor devices having an improved backside contact metal fill.

As semiconductor footprints continue to get smaller, the distances between different components in a semiconductor device continue to get smaller. Gate pitches (spacing), for instance, continue to reduce, raising concerns about unfavorable contact between the source/drain contacts and the gate. Furthermore, for improved device performance, three-dimensional transistors, such as those constructed on fin-type active areas, are frequently desired. FinFETs are another name for those three-dimensional field effect transistors (FETs) created on fin-type active areas. GAA FETs are another type of three-dimensional field-effect transistor. Because such FETs have a modest fin width for short channel control, their source/drain regions are smaller than those of planar FETs. These reduced alignment margins and reduced fin widths might be problematic when device pitches continue to contract and packing densities rise. Further, there is a tendency to create power lines on the substrate's back side. The backside power rails that are in use, however, continue to suffer a number of difficulties, such as shorting, leakage, routing resistance, alignment margins, layout flexibility, and packing density.

Future CMOS scaling is made possible by Direct Backside Contact (DBC), which successfully offers wiring alternatives on the wafer's backside. The DBC process can be used on any cell-to-cell space, which allays worries about narrow space formations in the front end of line (FEOL) and/or middle of line (MOL) during semiconductor production. Additionally, performance comprising high aspect ratio (AR) backside power rails (VBPR), which are commonly seen in conventional non-DBC processes, are not necessary for the DBC process.

In DBC fabrication procedures, a backside source/drain contact that corresponds to the underlying source/drain (S/D) area may be formed. The approach used to create the source/drain contact involves employing lithography patterning and etching techniques to create a deep trench in the source/drain region.

### SUMMARY

According to an embodiment of the disclosure, a semiconductor device having a backside contact is provided. The semiconductor device includes a substrate extending along a first axis to define a length, a second axis orthogonal to the first axis to define a width, and a third axis orthogonal to the first and second axes to define a height. There is also a first source/drain element on a first side of the semiconductor device and a second source/drain element on an opposing side of the semiconductor device along with a backside contact that comprises a first contact end on a first end of the first source/drain element and an opposing contact end in electrical communication with a backside power distribution network. A critical dimension of the first contact end is smaller than the critical dimension of the opposing contact end, and the backside contact is substantially aligned to the first source/drain element. There is also a source/drain placeholder material that comprises a second contact end on a second end of the second source/drain element and another opposing contact end on a opposite side of the second contact end, the critical dimension of a middle portion of the source/drain placeholder material being larger than the critical dimension of both the second contact end and the another opposing contact end.

In one embodiment, the source/drain placeholder material comprises SiGe.

In one embodiment, the source/drain placeholder material has a diamond shape.

According to an embodiment of the disclosure, a semiconductor fabrication method is disclosed. The method comprises patterning a portion of a semiconductor to define a channel region between a first designated source/drain region and a second designated source/drain region, forming a first source/drain trench in a first portion of the semiconductor substrate located in the first designated source/drain channel region, and forming a second source/drain trench in a second portion of the semiconductor substrate located in the second designated source/drain channel region. In the method, a depth of the first source/drain trench is extended to define a source/drain deep trench while maintaining a depth of the second source/drain trench. A deep trench source/drain placeholder material is formed in the source/drain deep trench and a source/drain placeholder material is formed in the second source/drain trench. A first source/drain element is formed on the deep trench source/drain placeholder material and a second source/drain element is formed on the source/drain placeholder material. In the method, the semiconductor substrate is flipped, a base of the semiconductor substrate is removed, and selective placeholder material is grown to modify the deep trench source/drain placeholder material and the source/drain placeholder material.

In one embodiment, the growing results in a critical dimension of a middle portion of the deep trench source/drain placeholder material being larger than both the critical dimension of a first end of the deep trench source/drain placeholder material that contacts the first source/drain element and the critical dimension of another end of the deep trench source/drain placeholder material opposite the first end.

In one embodiment, the growing results in a critical dimension of a middle portion of the source/drain placeholder material being larger than both the critical dimension of a first end of the source/drain placeholder material that contacts the second source/drain element the critical dimension of another end of the source/drain placeholder material opposite the first end.

In one embodiment, forming the first source/drain element and the second source/drain element involves epitaxially growing the first source/drain element from the deep trench source/drain placeholder material and epitaxially growing the second source/drain element from the source/drain placeholder material.

In one embodiment, the backside contact height is formed to be larger than the placeholder height.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 depicts cross section views of a semiconductor device illustrating a starting substrate in accordance with an illustrative embodiment.

FIG. 2 depicts cross section views of the semiconductor device after applying various fabrication processes on the starting substrate in accordance with an illustrative embodiment.

FIG. 3 depicts cross section views of the semiconductor device following one or more subsequent fabrication processes in accordance with an illustrative embodiment.

FIG. 4 depicts cross section views of the semiconductor device following one or more subsequent fabrication processes in accordance with an illustrative embodiment.

FIG. 5 depicts cross section views of the semiconductor device following one or more subsequent fabrication processes in accordance with an illustrative embodiment.

FIG. 6 depicts cross section views of the semiconductor device following one or more subsequent fabrication processes in accordance with an illustrative embodiment.

FIG. 7 depicts cross section views of the semiconductor device following one or more subsequent fabrication processes in accordance with an illustrative embodiment.

FIG. 8 depicts cross section views of the semiconductor device following one or more subsequent fabrication processes in accordance with an illustrative embodiment.

FIG. 9 depicts cross section views of the semiconductor device following one or more subsequent fabrication processes in accordance with an illustrative embodiment.

FIG. 10 depicts cross section views of the semiconductor device following one or more subsequent fabrication processes in accordance with an illustrative embodiment.

FIG. 11 depicts cross section views of the semiconductor device following one or more subsequent fabrication processes in accordance with an illustrative embodiment.

FIG. 12 depicts cross section views of the semiconductor device following one or more subsequent fabrication processes in accordance with an illustrative embodiment.

FIG. 13 depicts cross section views of the semiconductor device following one or more subsequent fabrication processes in accordance with an illustrative embodiment.

FIG. 14 depicts cross section views of the semiconductor device following one or more subsequent fabrication processes in accordance with an illustrative embodiment.

FIG. 15 depicts cross section views of the semiconductor device following one or more subsequent fabrication processes in accordance with an illustrative embodiment.

FIG. 16 depicts cross section views of the semiconductor device following one or more subsequent fabrication processes in accordance with an illustrative embodiment.

### DETAILED DESCRIPTION

Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The fabrication of the structures discussed herein can comprise multi-step sequences of, for example, photolithographic and/or chemical processing steps that facilitate gradual creation of electronic-based systems, devices, components, and/or circuits in a semiconducting and/or a superconducting device (e.g., an integrated circuit). For instance, devices herein can be fabricated on one or more substrates (e.g., a silicon (Si) substrates, and/or another substrate) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

Turning now to an overview of technologies that generally relate to the present teachings, Direct Backside Contact (DBC) fabrication can involve depositing a sacrificial placeholder material in a deep trench, followed by source/drain (S/D) epitaxy (epi) formation over the sacrificial placeholder. However, the deep trenches and/or sacrificial material for sacrificial placeholder formation may not be formed beneath all S/D regions of the semiconductor device. As a result, non-uniform source/drains may be formed between growing a S/D epi material from the top surface of the sacrificial placeholder and growing the source/drain epi over non-sacrificial placeholder region during the source/drain epi process. Further, during substrate removal, the shape of sacrificial placeholder material may be altered due to, for example, unintended removal of portions of the sacrificial placeholder material along with the substrate material.

Various non-limiting embodiments of the present disclosure provide fabrication methods and resulting semiconductor devices that implement source/drain placeholder elements to improve epitaxy growth uniformity when forming the source/drains and to improve backside contact metal fill. The source/drain placeholder is formed in the source/drain trenches prior to performing the source/drain epi process such that the bottom surfaces of all the source/drain trenches are aligned. In this manner, uniform source/drains can be formed following the source/drain epi process. Further, by modifying, based on selective epi growth, a shape of the placeholder material responsive to substrate base removal, an improved trench may be obtained to create an improved backside contact therein.

### Example Architecture

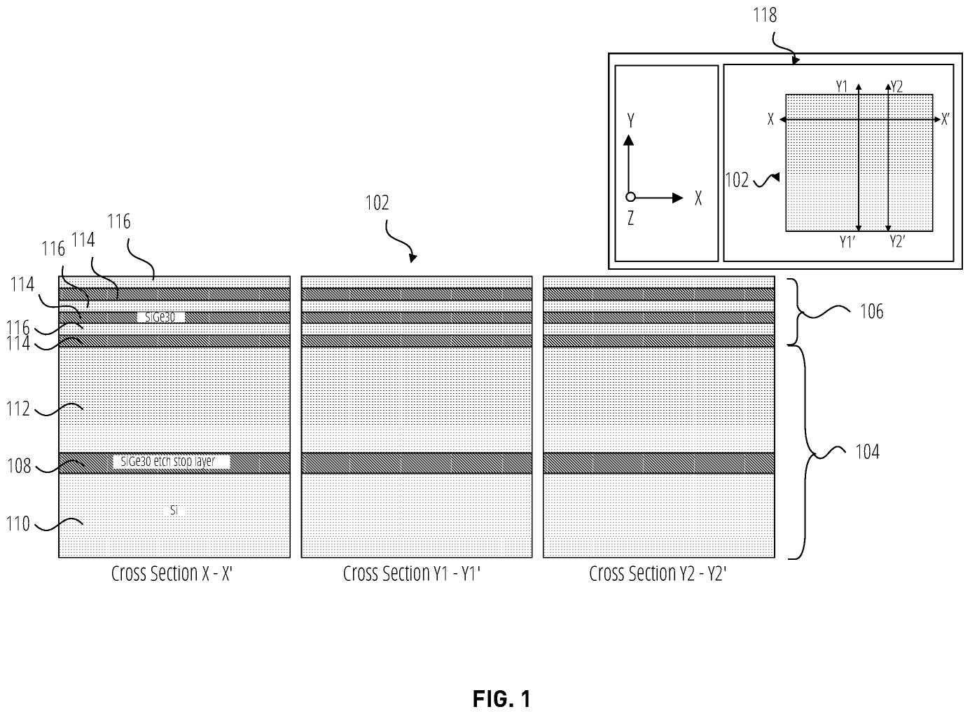

FIG. 1 illustrates cross sections X-X′, Y1-Y1′ and Y2-Y2′ of an example starting semiconductor substrate 102 used to fabricate a semiconductor device described herein following various fabrication processes. The semiconductor top view 118 illustrates the lines through which a plane is passed to obtain the cross sections. The starting semiconductor substrate 102 may extend along a first axis (e.g., X-axis) to define length, a second axis (e.g., Y-axis) orthogonal to the X-axis to define a width, and a third axis orthogonal to the first and second axes to define a height.

The starting semiconductor substrate 102 may comprise a substrate base 104 and a semiconductor stack 106 formed on an upper surface of the substrate base 104. The substrate base 104 may comprise an etch stop layer 108 embedded between a lower base portion 110 and an upper base portion 112 of the substrate base 104. The substrate base 104 (including the lower and upper base portions) can be formed from a semiconductor material such as, for example, silicon (Si). The starting semiconductor substrate 102 or wafer can be made of any suitable substrate material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

The etch stop layer 108 can be formed from various oxide materials including, but not limited to, silicon oxide (SiO2). In some embodiments, the etch stop layer 108 can be formed from silicon germanium (e.g., SiGe30). The etch stop layer 108 can have a thickness (e.g., in the Z-axis direction) ranging from about 5 nm to about 100 nm. The etch stop layer 108 can be utilized to serve as etch stop layer during removal of the lower base portion 110 during backside processing.

The semiconductor stack 106 may comprise an alternating stacked arrangement of sacrificial layers 114 and active semiconductor layers 116. In one or more non-limiting embodiments, the sacrificial layers 114 and the active semiconductor layers 116 may be formed as nanosheets, where the active semiconductor layers 116 serve as channel layers as described herein. Although three active semiconductor layers 116 are shown, more or fewer active semiconductor layers 116 may be used, and the number of sacrificial layers 114 may be increased or decreased accordingly.

In one or more non-limiting embodiments, the sacrificial layers 114, the active semiconductor layers 116, and the bottom sacrificial layer 114 may be epitaxially grown. The material of the sacrificial layers 114 may comprise SiGex %, for example, where the atomic percent % for “x” ranges from about 15-35% atomic percent. The material of the active semiconductor layers 116 may include, for example, Si. The thickness or height (e.g., along the Z-axis) of each sacrificial layer 114 may be range from about 5 nm to 15 nm, and the thickness or height of each active semiconductor layer 116 may range from about 5 nm to 15 nm.

Epitaxial materials may be grown from gaseous or liquid precursors using, for example, vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be doped during deposition (in-situ doped) by adding dopants, n-type dopants (e.g., phosphorus or arsenic) or p-type dopants (e.g., boron or gallium), depending on the type of transistor.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments of the disclosure, epitaxial growth and/or deposition processes are selective to forming on semiconductor surfaces, and generally do not deposit material on non-crystalline surfaces such as silicon dioxide or silicon nitride.

In some embodiments of the disclosure, the gas source for the deposition of epitaxial semiconductor material may include a silicon containing gas source, a germanium containing gas source, or a combination thereof. For example, an epitaxial Si layer may be deposited from a silicon gas source that is selected from the group consisting of silane, disilane, trisilane, tetrasilane, hexachlorodisilane, tetrachlorosilane, dichlorosilane, trichlorosilane, methyl silane, dimethyl silane, ethyl silane, methyl disilane, dimethyl disilane, hexamethyldisilane and combinations thereof. An epitaxial germanium layer may be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

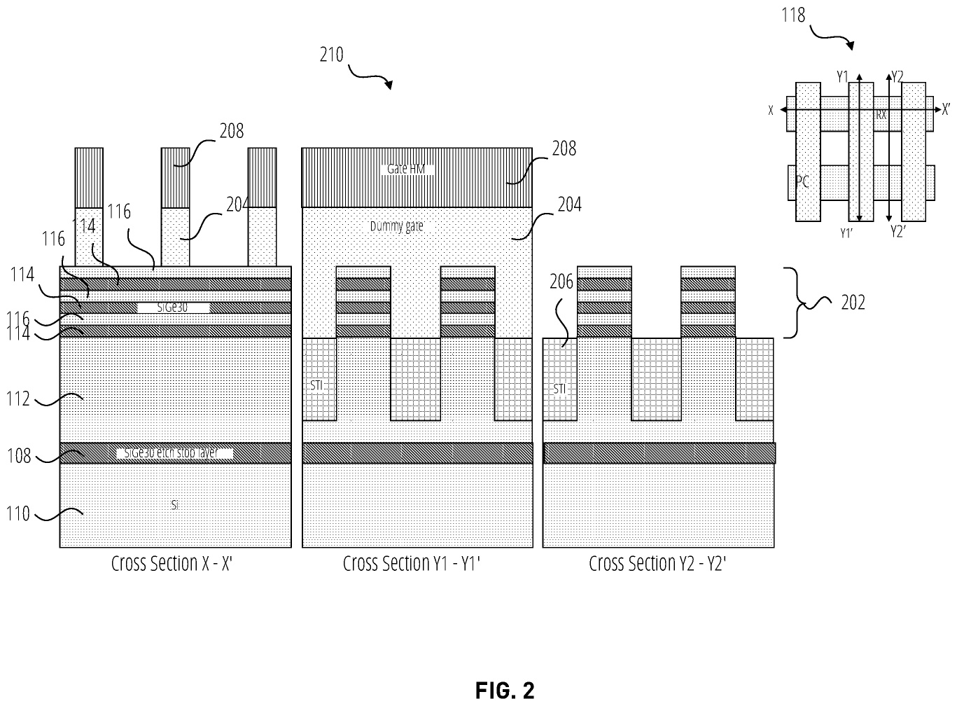

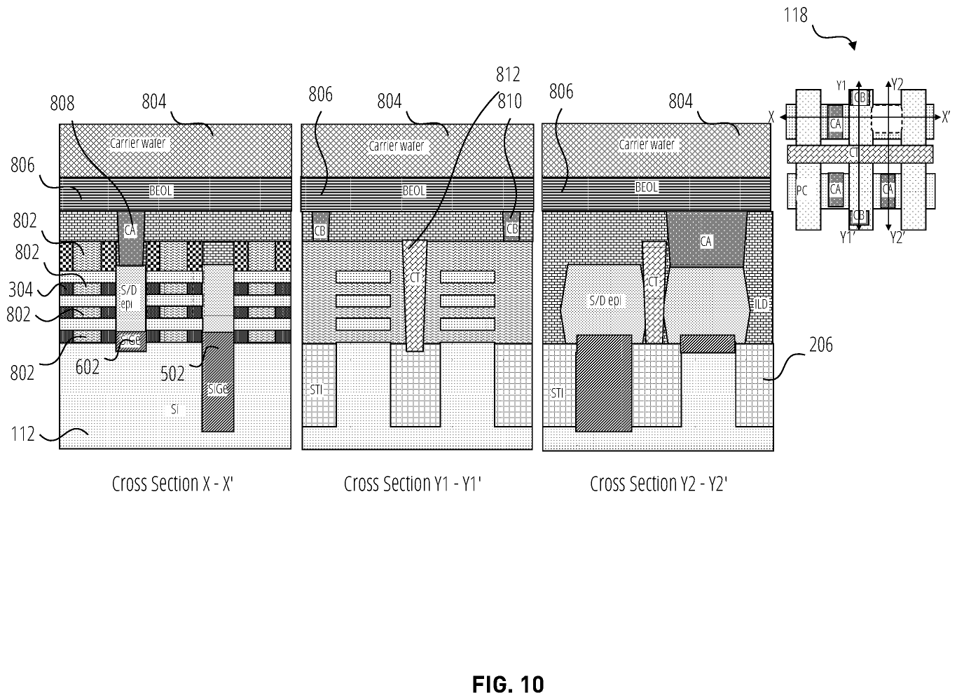

FIG. 2 illustrates the performance of various fabrication processes on the starting semiconductor substrate 102 to produce a semiconductor device 210 an intermediate stage. The semiconductor top view 118 of FIG. 2 further shows gates (PC) and active regions (RX). As described herein, a semiconductor device 210 is shown in FIG. 2 to FIG. 16 and may be in an intermediate stage wherein the semiconductor device is a stage of fabrication prior to a final stage. The fabrication processes include depositing a hard mask layer (not shown) over the semiconductor stack 106 and the hard mask layer and the semiconductor stack 106 are etched to define a nanosheet stack 202 having trenches. Thereafter, shallow trench isolation (STI) 206 regions may be formed by overfilling the trenches with dielectric material. This is followed by chemical mechanical planarization (CMP) and dielectric recess, and the hardmask layer is removed.

A dummy gate 204 may be deposited and patterned. The dummy gate 204 being formed over the nanosheet stack 202. A gate hard mask 208 is formed on an upper surface of the dummy gate 204. The dummy gate 204 may represent a combination of a thin layer of gate oxide (e.g., SiO2) and a dummy gate material (e.g., amorphous silicon (a-Si)) from which the dummy gates 204 are formed. It should be appreciated that various known fabrication operations (e.g., an RIE) can be used to form dummy gates 204. In embodiments of the disclosure, the dummy gates 204 may be formed by depositing and planarizing a layer of dummy gate material over a gate oxide (not shown separately from the active semiconductor layer 116). In some embodiments of the disclosure, the dummy gate material may be polycrystalline Si. In some embodiments of the disclosure, the dummy gate material may be amorphous Si (a-Si). After being deposited, the dummy gate material is planarized (e.g., by CMP) to a desired level.

Various known semiconductor fabrication operations may be used to form the gate hard masks 208 on the upper surface of the dummy gate 204. The pattern used to form the gate hard masks 208 defines the footprint of the underlying dummy gates 204. In embodiments of the disclosure, the gate hard masks 208 can be formed from oxide and/or nitride materials. In embodiments of the disclosure, the gate hard masks 208 can be formed by depositing a layer of hard mask material and patterning then etching the deposited hard mask layer to form the gate hard masks 208. The dummy gate material may be selectively etched such that portions of the dummy gate material that are not under the gate hard masks 208 are selectively removed, thereby forming the dummy gates 204 over the nanosheet stack 202. Known fabrication operations may be used to selectively remove the portions of the gate oxide (not shown) that are not under the dummy gates 204, and a dilute hydrofluoric acid (DHF) cleaning process may be performed to ensure that all of the gate oxide that is not under the dummy gates 204 is removed.

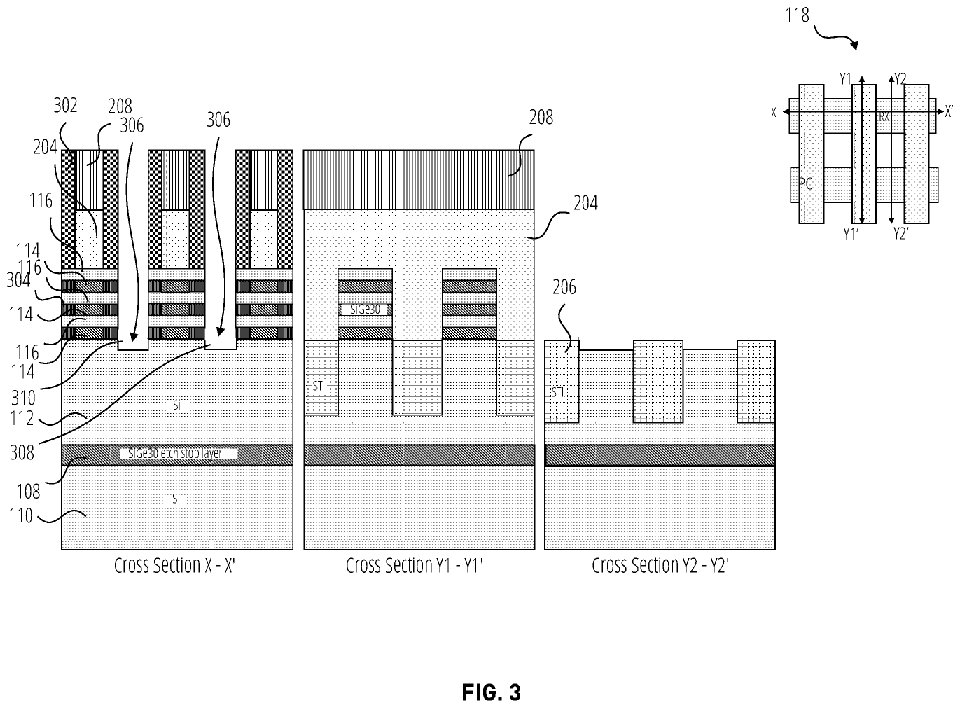

Turning now to FIG. 3, known fabrication operations may be used to deposit a dielectric material used to form the gate spacers 302 on sidewalls of the dummy gates 204 and the gate hard masks 208, and recessing the nanosheet stack 202 in the first region 308 and second region 310 to form source/drain trenches 306. The position of the first region 308 and second region 310 are shown for illustrative purposes and not meant to be limiting. For example, in an illustrative embodiment, the positions of first region and second region may be switched. In some embodiments of the disclosure, the gate spacers 302 can be formed by depositing the dielectric material over the dummy gates 204 and the gate hard masks 208, and then directionally etching (e.g., using an RIE) the dielectric material to form the gate spacers 302. In embodiments of the disclosure, the gate spacers 302 can be formed from any suitable dielectric material including, for example, silicon oxide, silicon nitride, silicon oxynitride, SiBCN, SiOCN, SiOC, or any suitable combination of those materials. In some embodiments of the disclosure, the gate spacers 302 can be a low-k dielectric material.

Further, the fabrications process includes partially removing end regions of the sacrificial nanosheets (generally referred to as sacrificial layers 114 prior to forming the nanosheet stack 202) to form end region or inner spacer cavities (not shown). In embodiments of the disclosure, the end regions of the sacrificial nanosheets/sacrificial layers 114 may be removed using a technique referred to as a “pull-back process” to pull back the sacrificial nanosheets to an initial pull-back distance such that the ends of SiGe sacrificial nanosheets terminate at about an inner edge of the gate spacers 302. In embodiments of the disclosure, the pull-back process leverages material properties of the sacrificial nanosheets, which in this example may be formed from SiGe and therefore may be selectively etched with respect to the active semiconductor nanosheets (generally referred to as active semiconductor layers 116 prior to forming the nanosheet stack 202) using, for example, a vapor phase hydrogen chloride (HCl) gas isotropic etch process.

A layer of inner spacer material may be conformally deposited over the nanosheet-based structure using, for example, an atomic layer deposition (ALD) process. The inner spacer layer can be silicon nitride, silicoboron carbonitride, silicon carbonitride, silicon carbon oxynitride, or any other type of dielectric material (e.g., a dielectric material having a dielectric constant k of less than about 5). An isotropic etch back process, for example, can then be performed to remove the inner spacer material everywhere except the cavity regions created by SiGe indentation. Accordingly, the portions of the inner spacer material filling the inner spacer cavities are maintained to form inner spacers 304 and the upper surfaces shallow trench isolation (STI) 206 are exposed.

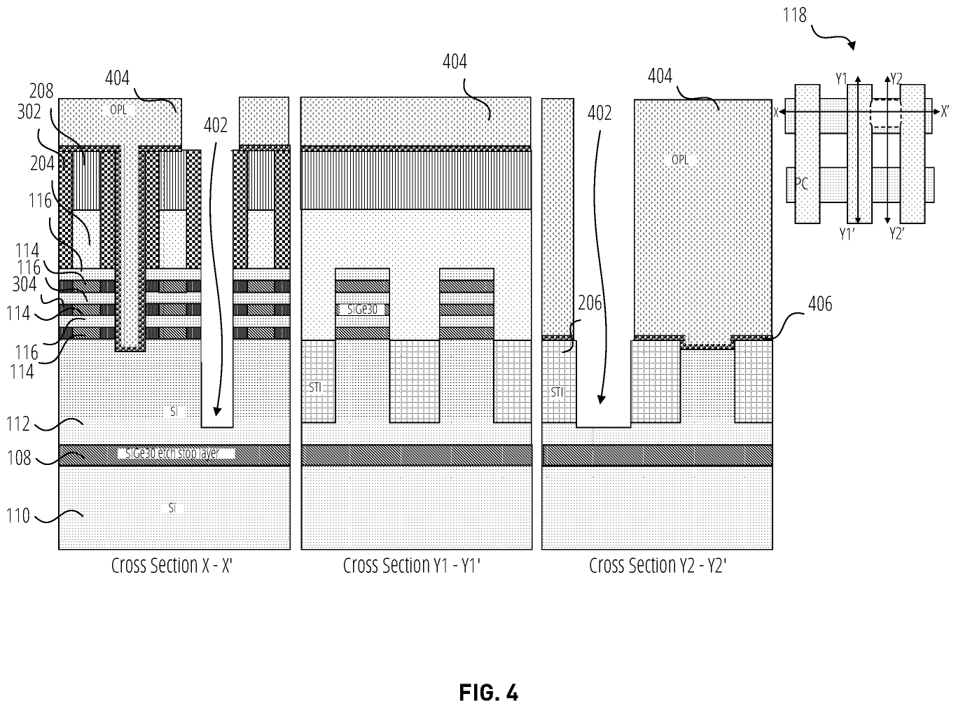

As shown in FIG. 4, one or more of the source/drain trenches 306 (such as the source/drain trench in the first region 308) are further extended into the substrate base 104 to form a source/drain deep trench 402. In one or more non-limiting embodiments, the source/drain deep trench 402 may be formed by depositing a protecting liner 406 and a pattern soft mask 404 (such as an organic planarization layer) on an upper surface of the semiconductor device to cover the hard mask elements and fill the source/drain trenches 306. The pattern soft mask 404 may then be patterned using known lithography and patterning techniques such that a targeted source/drain trench 306 (such as the source/drain trench in the first region 308) is exposed, while remaining portions of the semiconductor device remain covered.

The exposed targeted source/drain trench 306 may then be further recessed to form the source/drain deep trench 402 using a RIE process, for example, to increase its depth below that of the covered source/drain trench. In one or more non-limiting embodiments, the RIE processed may be performed to increase the depth of the targeted source/drain trench 306.

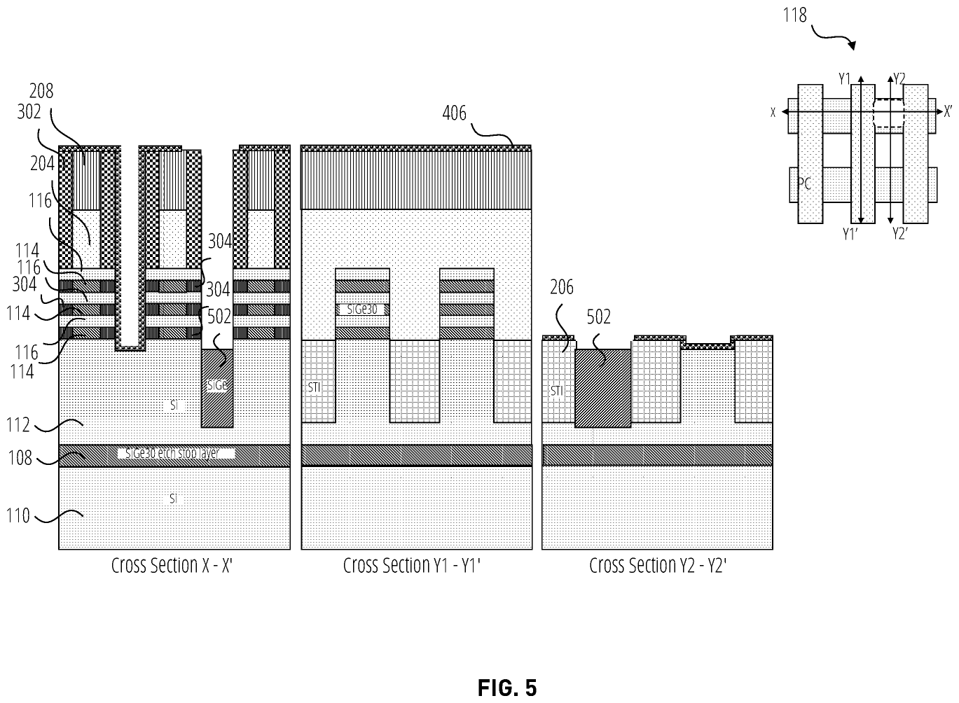

As shown in FIG. 5, the OPL is stripped, and a bottom-up epi is grown in the source/drain deep trench 402. The epi may be a sacrificial deep trench source/drain placeholder material and may include various materials such as SiGe.

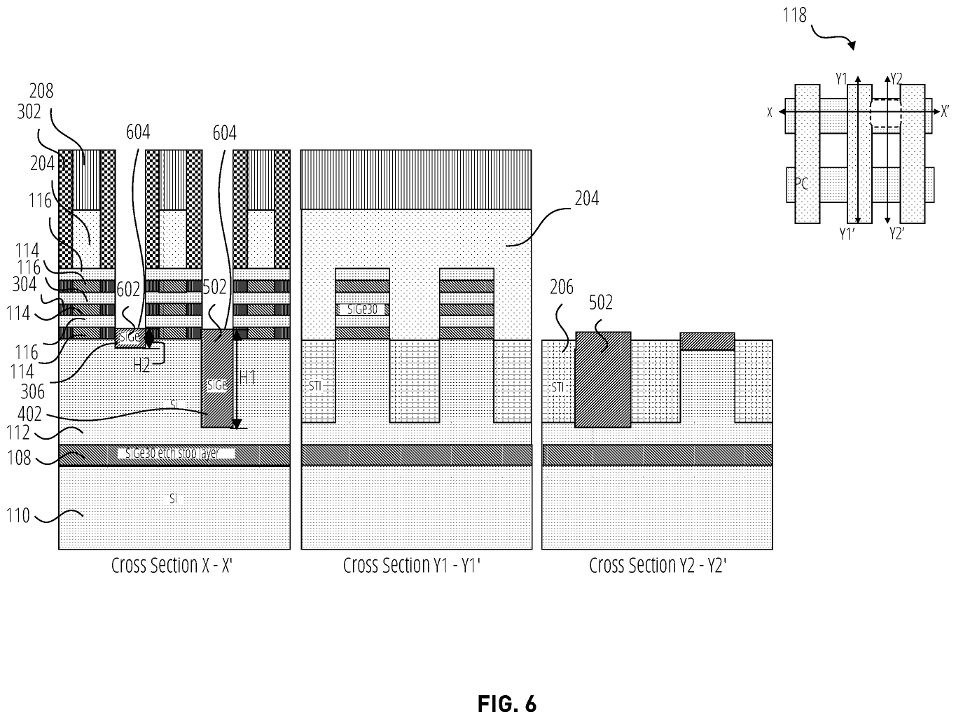

In subsequent processes as shown in FIG. 6, the protecting liner 406 is removed additional bottom-up epi may be grown in every source/drain trench's bottom. The bottom-up epi in all the source/drain trenches may be grown in such a way that a top surface of the placeholder materials formed reach a targeted depth just below the very bottom active semiconductor layer 116, wherein the top surfaces are coplanar. This may allow subsequently formed source/drain elements, formed on the top surfaces 604 of the placeholder materials (deep trench source/drain placeholder material 502 and source/drain placeholder material 602), to be uniform. In some non-limiting embodiments of the disclosure, the targeted depth may such that the top surface 604 of the placeholder material is above the upper surface of the substrate upper base portion 112. Further, as shown in FIG. 6, the deep trench source/drain placeholder material 502 formed in the source/drain deep trench 402 has a larger height H1 (e.g., extends into the substrate base 104 at a greater depth) with respect to a height H2 of the source/drain placeholder material 602 formed in the remaining source/drain trench 306 due to the increased depth of the source/drain deep trench 402. However, the top surfaces 604 of the placeholder elements located in the source/drain trench 306 are aligned, or substantially aligned (e.g., along the X-axis and Y-axis), with the upper surface of the deep trench placeholder element located in the source/drain deep trench 402 because the sacrificial placeholder material deposited in the source/drain trench 306 and the source/drain deep trench 402 are recessed together at the same time. The aligned upper surfaces of the placeholder elements therefore facilitate the uniform formation of epi grown source/drain elements as described in greater detail below.

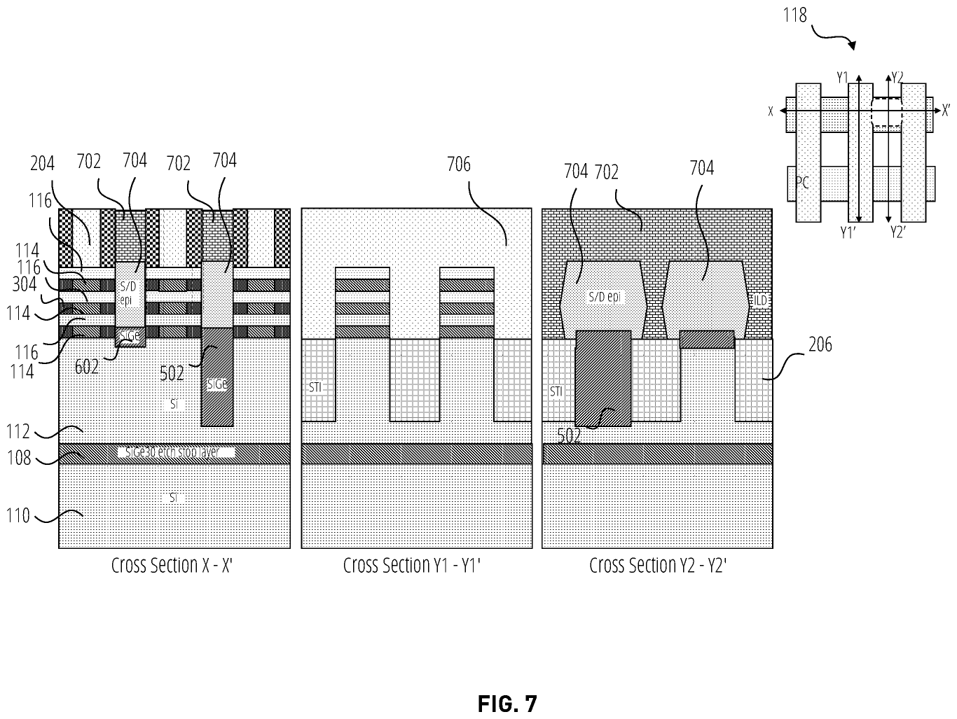

FIG. 7 shows the formation of source/drain elements 704 in the source/drain trench 306 and the source/drain deep trench 402. In one or more non-limiting embodiments, the source/drain elements 704 may be formed by performing an epi growth process to grow a semiconductor material from the exposed semiconductor surfaces with upper surface of the placeholder elements 602 and 502 exposed. In one more non-limiting embodiments, the epi growth process may be performed until the epi material reaches the upper surface of portions of the gate spacers 302 located in the designated source/drain regions. All the source/drain regions may have similar exposed sidewall surfaces of nanosheets and exposed surfaces of sacrificial placeholder material, thus facilitating uniform formation of the source/drain elements 704 due to the uniform surrounding materials. The source/drain elements may be formed using source/drain epi growth and may comprise 100 bottom-up. This may produce high quality epis with lower defects compared to nucleating from channel nanosheets sidewall.

The fabrication process may further include depositing an interlayer dielectric 702 on the semiconductor device to cover the source/drain elements 704 and the nanosheet stacks 202, and then recessing the interlayer dielectric 702 (e.g., using a CMP process) until stopping on an upper surface of the dummy gate 204 located in the designated gate region.

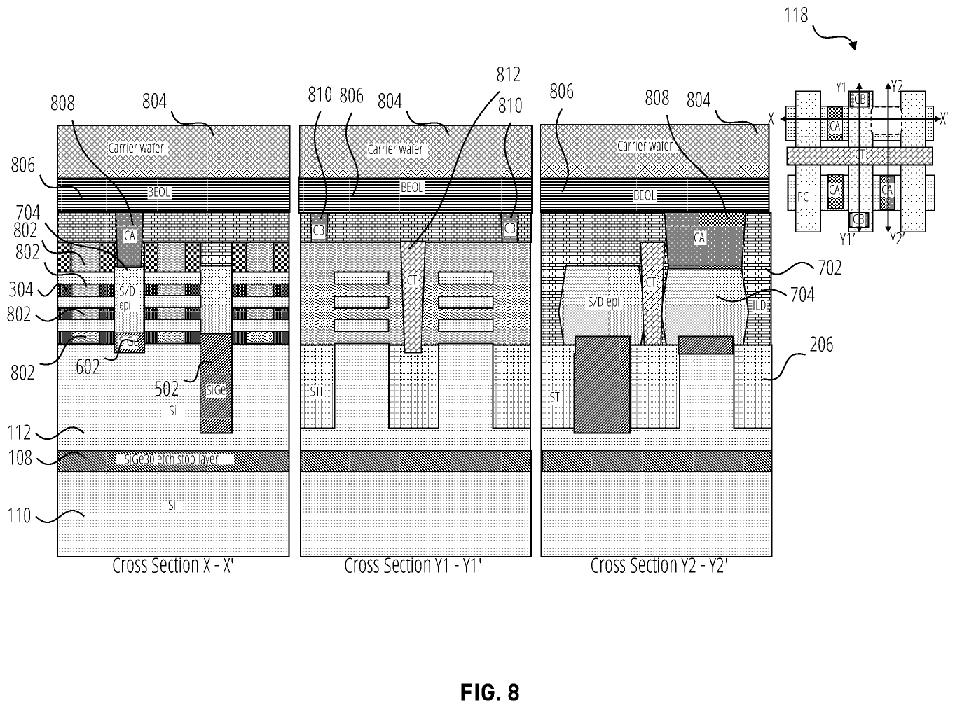

Turning now to FIG. 8, the fabrication process is further illustrated wherein the dummy gate 204 is selectively removed to expose the underlying nanosheet stack 202. Upon exposing the nanosheet stack, the sacrificial layers 114 may be selectively removed with respect to the active nanosheets 116. In one or more non-limiting embodiments of the disclosure, an etching chemistry is chosen that etches the material of the sacrificial nanosheets without attacking, or substantially attacking, the active nanosheets. In this manner, the active nanosheets may be “released” (not shown). A gate is formed to surround or “wrap around” the released active nanosheets. In one or more non-limiting embodiments, the gate can be a high-k dielectric metal gate 802 (HKMG) formed to surround the released active nanosheets using, for example, known replacement metal gate (RMG) processes, or so-called gate-first processes. Accordingly, the released active nanosheets serve as the “channel region” around which the gate is formed, and through which a current passes from the source to the drain in the final device.

In one or more non-limiting embodiments, the gate 802 can include known gate dielectric(s) (not shown) and known work function metal stacks (not shown) appropriate for NFET or PFET devices. In some embodiments of the disclosure, the gate dielectric is a high-k dielectric film. The high-k dielectric film can be made of, for example, silicon oxide, silicon nitride, silicon oxynitride, boron nitride, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k materials can further include dopants such as lanthanum and aluminum. In some embodiments of the disclosure, the high-k dielectric film can have a thickness of about 0.5 nm to about 4 nm. In some embodiments of the disclosure, the high-k dielectric film includes hafnium oxide and has a thickness of about 1 nm, although other thicknesses are within the contemplated scope of the disclosure. In some embodiments of the disclosure, one or more work function layers are positioned between the high-k dielectric film and a bulk gate material.

In some embodiments of the disclosure, the gate includes one or more work function layers, but does not include a bulk gate material. If present, the work function layers can be made of, for example, aluminum, titanium nitride, tantalum nitride, hafnium nitride, tungsten nitride, molybdenum nitride, niobium nitride, hafnium silicon nitride, titanium aluminum nitride, tantalum silicon nitride, titanium aluminum carbide, tantalum carbide, and combinations thereof. The work function layers can serve to modify the work function of the gate and enables tuning of the device threshold voltage. The work function layers can be formed to a thickness of about 0.5 to 6 nm, although other thicknesses are within the contemplated scope of the disclosure. In some embodiments of the disclosure, each of the work function layers can be formed to a different thickness. In some embodiments, the gate comprises a main body formed from bulk conductive gate material(s) deposited over the work function layers and/or gate dielectrics. The bulk gate material can include any suitable conducting material, such as, for example, metal (e.g., tungsten, titanium, tantalum, ruthenium, zirconium, cobalt, copper, aluminum, lead, platinum, tin, silver, gold), conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), conductive carbon, graphene, or any suitable combination of these materials. The conductive gate material can further include dopants that are incorporated during or after deposition. After that, gate cut (CT) region is formed by conventional patterning and dielectric fill process.

With reference still to FIG. 8, the semiconductor device is illustrated after performing various middle-of-line (MOL) and backend-of-line (BEOL) fabrication processes. The MOL fabrication process may comprise forming one or more source/drain contacts 808 (CA) to enable electrical connection to the source/drain elements 704, and gate contact 810 (CB) to enable electrical connection to the gate 802. The source/drain contacts 808 and gate contact 810 can be formed using known lithography and patterning techniques. For example, a mask layer (not shown) can be deposited on the upper surface of the interlayer dielectric 702 and patterned to exposed portions of the interlayer dielectric 702 designated to contain a respective source/drain contact 808. The exposed portions of the interlayer dielectric 702 can then be etched to form source/drain contact trenches (not shown) that stop on an upper surface of the underlying source/drains source/drain elements 704. The source/drain contact trenches may then be filled with an electrically conductive material and planarized (e.g., using CMP) to form the source/drain contacts 808. The electrically conductive material includes, for example, a silicide layer such as Ni Si, Ti Si or NiPtSi, and metal adhesion layers, such as TiN, and a conductive metal, such as W, Co, Ru, etc.

A BEOL interconnect layer 806 can be formed on an upper surface of interlayer dielectric 702. The BEOL interconnect layer 806 can be formed with multiple layers of electrically conductive (e.g., copper (Cu)) wires and vias with low-k dielectrics filled in between. In one or more non-limiting embodiments, the BEOL interconnect layer 806 directly contacts the upper surface of the source/drain contacts 808. Accordingly, an electrical path may be established from the BEOL interconnect layer 806 to the source/drain contacts 808. A carrier wafer 804 may then be bonded on an upper surface of the BEOL interconnect layer 146. The carrier wafer 804 may include a Si substrate that is bonded to the upper surface of the BEOL interconnect layer 806 and serves to support the semiconductor device when performing various backside fabrication processes discussed in greater detail below.

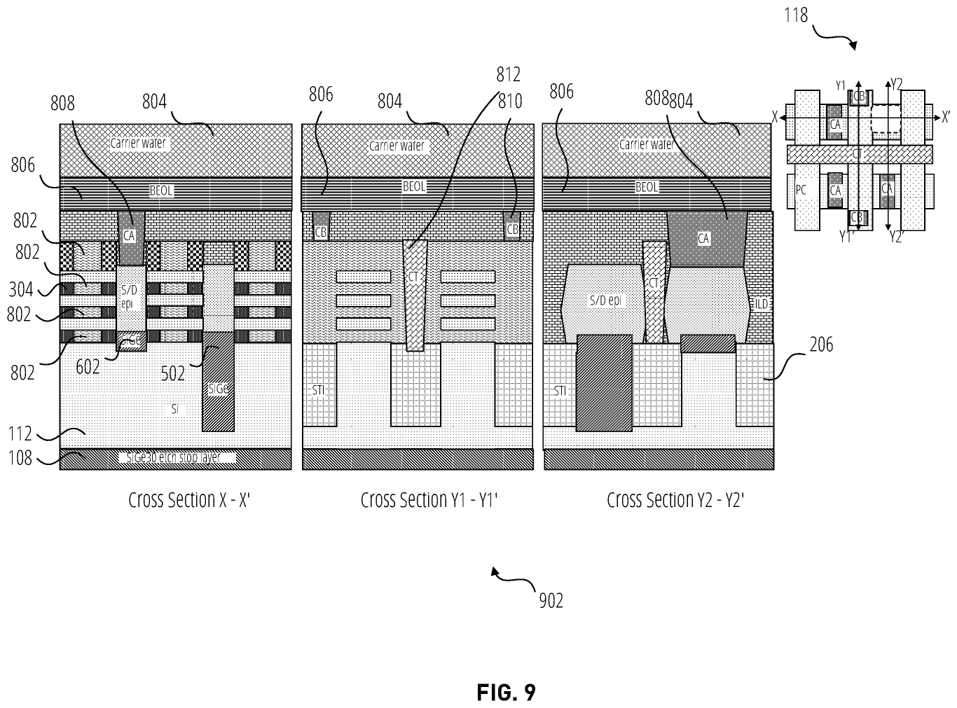

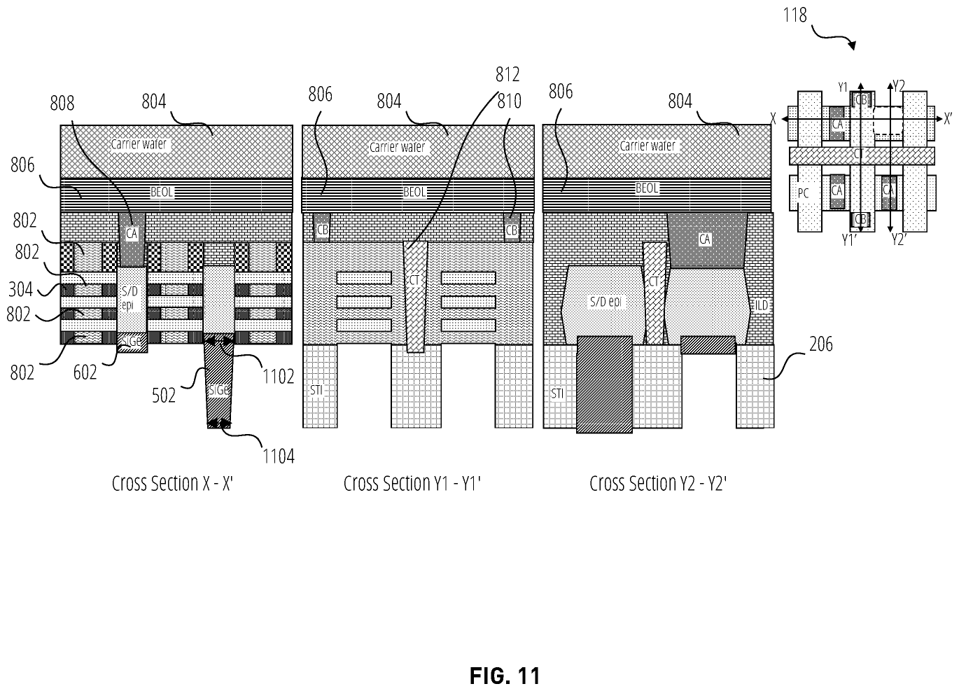

FIG. 9-FIG. 11 illustrate one or more fabrication processes including the flipping of the semiconductor device. Though not shown, the semiconductor device is flipped such that the bottom surface 902 becomes a top surface upon which the fabrication process continues. Responsive to the flipping, the lower base portion 110 of the substrate base 104 is recessed until the etch stop layer 108 is exposed. In one or more non-limiting embodiments, a selective wet and/or dry etch process can be performed and stops in response to reaching the etch stop layer 108 and exposing the etch stop layer surface. Further, in one or more non-limiting embodiments, selective wet and/or dry etch processes may be performed to remove the etch stop layer 108 and the upper base portion 112, thus exposing the placeholder material (deep trench source/drain placeholder material 502 and source/drain placeholder material 602) as well as the shallow trench isolation (STI) 206. The etch process may also be selective to HfO2, so gate 802 is not damaged during removal of 112. As shown in FIG. 11, removing the upper base portion 112 may result in damaging the placeholder material such as the deep trench source/drain placeholder material 502. For example, the shape of the deep trench source/drain placeholder material 502 may be altered/compromised during the removal process such that a first dimension of the deep trench source/drain placeholder material 502 at a region of the deep trench source/drain placeholder material 502 that is in contact with the corresponding source/drain element 704 (critical dimension A 1102) is not the same (i.e. larger) as a second dimension (critical dimension B 1104) at an opposite end of the deep trench source/drain placeholder material 502. This may result in poor backside metal fill.

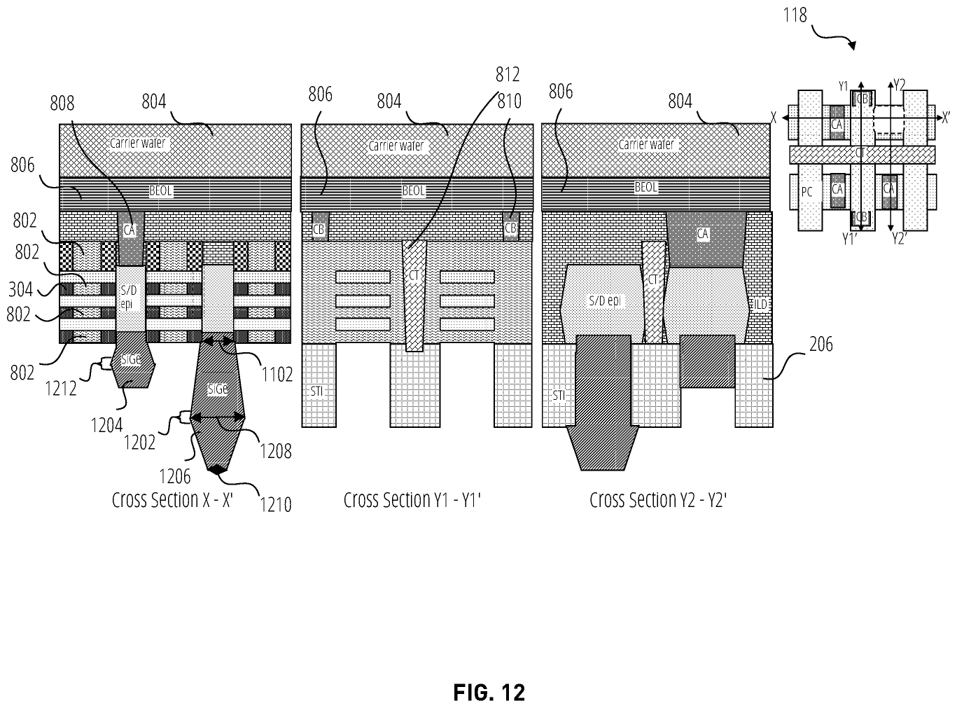

Turning now to FIG. 12, epi (e.g., SiGe) may be selectively grown to modify the shapes of the placeholder material such that the source/drain placeholder material 602 becomes a modified source/drain placeholder material 1204 and the deep trench source/drain placeholder material 502 becomes a modified deep trench source/drain placeholder material 1206. This results in a critical dimension C 1208 of a middle portion 1202 of the modified deep trench source/drain placeholder material 1206 being larger than the critical dimension A 1102 of a first end of the modified deep trench source/drain placeholder material 1206 that contacts the source/drain element 704 in the deep trench. Critical dimension C 1208 may also be larger than the critical dimension D 1210 of another end of the modified deep trench source/drain placeholder material 1206 opposite the first end. In an illustrative embodiment, critical dimension C 1208 was previously critical dimension B 1104 prior to said modification.

Further, the growing may result in a critical dimension of another middle portion 1212 of the modified source/drain placeholder material 1204 being larger than both the critical dimension of a first end of the modified source/drain placeholder material 1204 that contacts the corresponding source/drain element and the critical dimension of another end of the modified source/drain placeholder material 1204 opposite the first end. Even more specifically, the modified source/drain placeholder material 1204 may be diamond in shape.

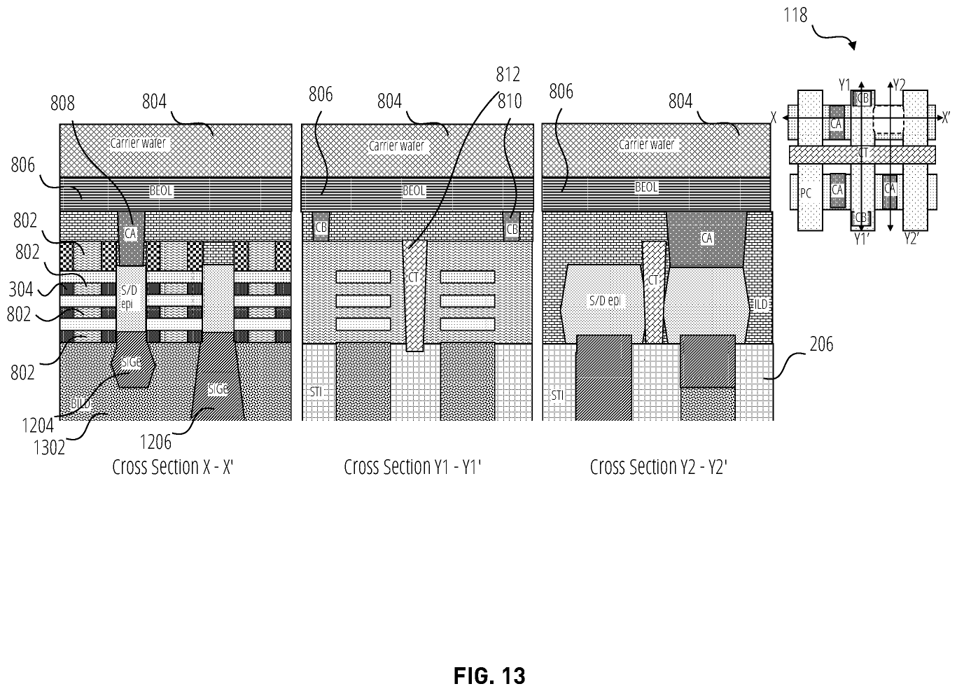

Turning now to FIG. 13, the semiconductor device is illustrated after depositing a backside interlayer dielectric 1302 to cover and encapsulate the modified placeholder materials 1204 and 1206. Following deposition of the backside interlayer dielectric 1302, a CMP process can be performed to planarize the backside interlayer dielectric 1302. The CMP process can stop on a surface of the modified deep trench source/drain placeholder material 1206 corresponding to the middle portion 1202, though this is not meant to be limiting.

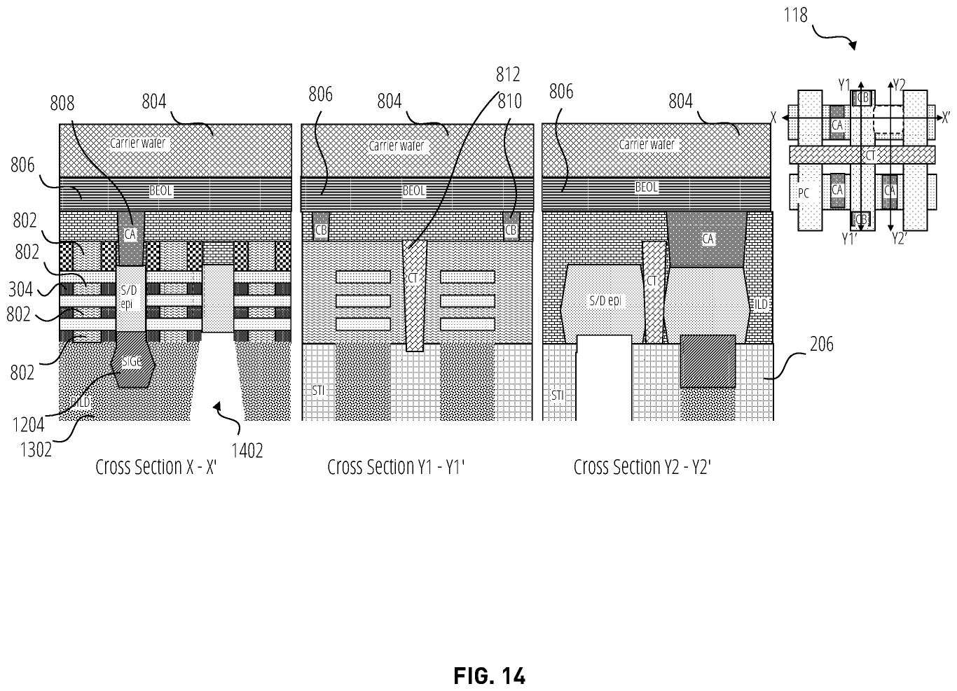

As shown in FIG. 14, the semiconductor device is illustrated following removal of the planarized modified deep trench source/drain placeholder material 1206. Accordingly, a backside trench 1402 is formed in the backside interlayer dielectric 1302 and exposes a portion of the source/drain element 704 in the first region 308. In one or more non-limiting embodiments, the modified deep trench source/drain placeholder material 1206 is removed, while the modified source/drain placeholder material 1204 in the second region is maintained in the backside interlayer dielectric 1302 since the source/drain element 704 in the second region 310 may not require connection with a backside contact.

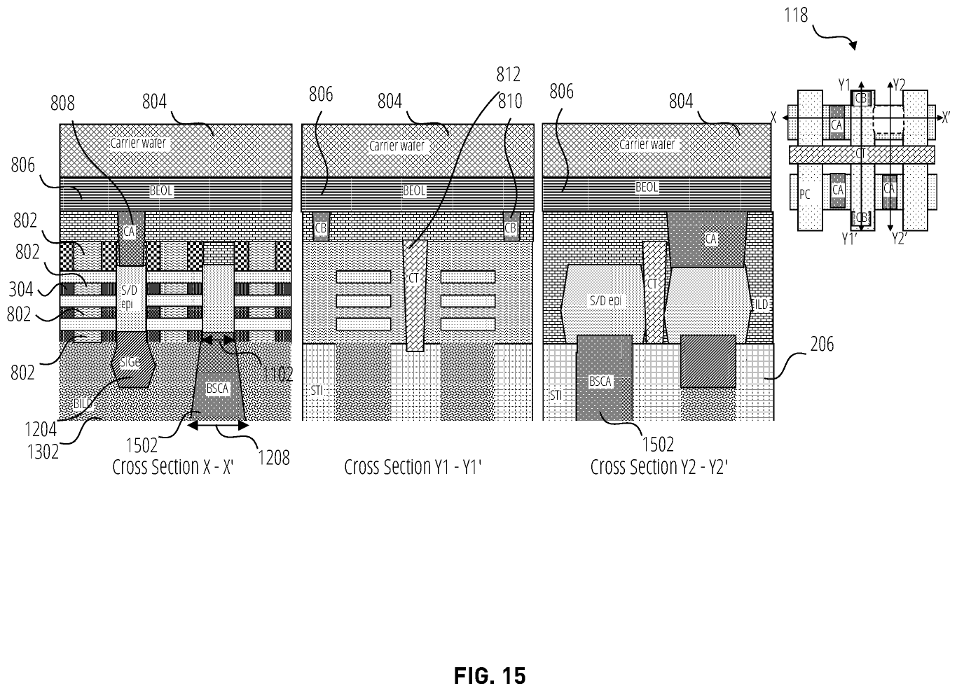

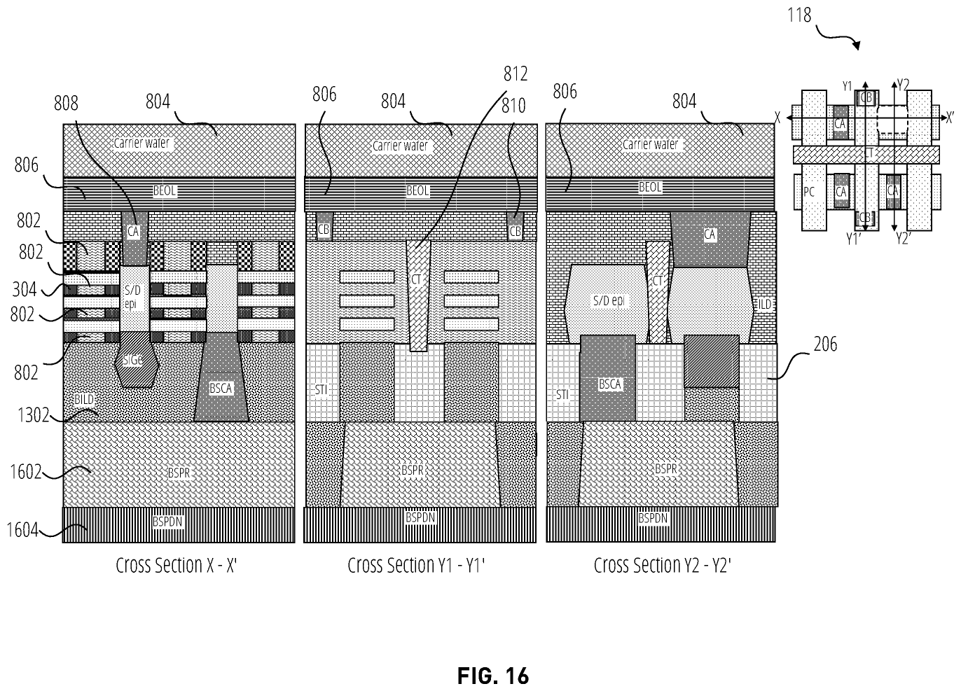

As shown in FIG. 15, an electrically conductive material is deposited in the backside trench 1402 to establish physical contact and electrical connection with the corresponding source/drain element 704. The electrically conductive material can be similar material as the material of the source/drain contact 808. In one or more non-limiting elements, the electrically conductive material over-fills the backside and a CMP process is performed to planarize the upper surfaces of the electrically conductive material and the backside interlayer dielectric 1302. The remaining electrically conductive material filling the deep trench forms a backside contact 1502, which establishes electrical connection with the underlying source/drain element 704. Further, the backside contact 1502 can establish connection between a source/drain element 704 and a backside power delivery network 1604 (FIG. 16), while one or more of the source/drain contacts 808 serve as a frontside contact to establish connection between a source/drain element 704 and a BEOL interconnect layer 806. According to one or more non-limiting embodiments, the backside contact 1502 may extends between a first source/drain element 704 (i.e., in the first region 308) and the backside power delivery network 1604 to define a contact height (e.g., extending along the Z-axis), and the modified source/drain placeholder material 1204 extends between a second source/drain element and the backside power distribution backside power delivery network 1604 to define a placeholder height that is less than the contact height of the backside contact 1502. In other words, the backside contact 1502 has a depth (e.g., a height extending along the Z-axis) that is greater than a depth (e.g., height extending along the Z-axis) of the modified source/drain placeholder material 1204.

Further, the backside contact 1502 is substantially aligned with the corresponding source/drain element (i.e., a first end of the backside contact 1502 that is in contact with the source/drain element 704 is not mismatched or offset from the contacting end of the source/drain element 704). Even further, as shown in FIG. 15, the critical dimension C 1208 of the backside contact 1502 is larger than the critical dimension A 1102 of the backside contact 1502.

As shown in FIG. 16, a backside power rail 1602 (BSPR) is formed to connect to the backside contact 1502. The backside power rail 1602 can be formed from a metal material such as copper, for example. In one or more non-limiting embodiments, the backside power rail 1602 directly contacts the surface of the backside contact 1502. Accordingly, an electrical path is established from the backside power rail 1602 to the backside contact 1502. A backside power delivery network 1604 (BSPDN) is formed on a surface of backside power rail 1602. The backside power delivery network 1604 may include additional backside metal and via levels formed within additional backside ILD. Accordingly, the backside power rail 1602 can be configured to provide power to the BSPDN.

While the manufacture of a semiconductor device with a first region 308 and a second region 310 is described for the purposes of discussion, it will be understood that other configurations, as well as those having source/drain epis where each source/drain epi has either placeholder material or backside contact are supported by the teachings herein. For example, in an illustrative embodiment, every source/drain epi may have a placeholder.

In one aspect, the method and structures as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device comprising:
a substrate extending along a first axis to define a length, a second axis orthogonal to the first axis to define a width, and a third axis orthogonal to the first and second axes to define a height;
a first source/drain element on a first side of the semiconductor device and a second source/drain element on an opposing side of the semiconductor device;
a backside contact including a first contact end on a first end of the first source/drain element and an opposing contact end in electrical communication with a backside power distribution network, a critical dimension of the first contact end being smaller than a critical dimension of the opposing contact end, and the backside contact being substantially aligned to the first source/drain element; and
a source/drain placeholder material including a second contact end on a second end of the second source/drain element and another opposing contact end on an opposite side of the second contact end, the critical dimension of a middle portion of the source/drain placeholder material being larger than the critical dimension of both the second contact end and the another opposing contact end.

2. The semiconductor device of claim 1, wherein the backside contact extends along the third axis between the first source/drain element and the backside power distribution network to define a backside contact height, and wherein the source/drain placeholder material extends between the second source/drain element and the backside power distribution network to define a placeholder height.

3. The semiconductor device of claim 2, wherein the backside contact height is larger than the placeholder height.

4. The semiconductor device of claim 1, wherein the source/drain placeholder material comprises SiGe.

5. The semiconductor device of claim 1, wherein the source/drain placeholder material has a diamond shape.

6. The semiconductor device of claim 1, further comprising a frontside contact including a first contact end on a first end of the second source/drain element and an opposing second contact end in electrical communication with a backend of line (BEOL) interconnect.

7. The semiconductor device of claim 1, further comprising a back side power rail positioned between the backside contact and the backside power distribution network.

8. A method of fabrication a semiconductor device, the method comprising:
patterning a portion of a semiconductor formed on semiconductor substrate to define a channel region between a first designated source/drain region and a second designated source/drain region;
forming a first source/drain trench in a first portion of the semiconductor substrate located in the first designated source/drain channel region and forming a second source/drain trench in a second portion of the semiconductor substrate located in the second designated source/drain channel region;
extending a depth of the first source/drain trench to define a source/drain deep trench while maintaining a depth of the second source/drain trench;
forming a deep trench source/drain placeholder material in the source/drain deep trench and a source/drain placeholder material in the second source/drain trench;
forming a first source/drain element on the deep trench source/drain placeholder material and a second source/drain element on the source/drain placeholder material;
flipping the semiconductor substrate;
removing a base of the semiconductor substrate; and
growing selective placeholder material to modify the deep trench source/drain placeholder material and the source/drain placeholder material.

9. The method of claim 8, further comprising forming a backside interlayer dielectric to expose the deep trench source/drain placeholder material while covering the source/drain placeholder material.

10. The method of claim 9, further comprising removing the deep trench source/drain placeholder material.

11. The method of claim 10, further comprising forming a backside contact in a space created by the deep trench source/drain placeholder material.

12. The method of claim 8, wherein growing the selective placeholder material results in a critical dimension of a middle portion of the deep trench source/drain placeholder material being larger than both the critical dimension of a first end of the deep trench source/drain placeholder material that contacts the first source/drain element and the critical dimension of another end of the deep trench source/drain placeholder material opposite the first end.

13. The method of claim 8, wherein growing the selective placeholder material results in a critical dimension of a middle portion of the source/drain placeholder material being larger than both the critical dimension of a first end of the source/drain placeholder material that contacts the second source/drain element the critical dimension of another end of the source/drain placeholder material opposite the first end.

14. The method of claim 8, wherein forming the deep trench source/drain placeholder material and the source/drain placeholder material comprises:
filling the source/drain deep trench and the second source/drain trench with a placeholder material; and
recessing the placeholder material until an upper surface of the placeholder material disposed in the source/drain deep trench and the second source/drain trench reach a targeted depth.

15. The method of claim 14, wherein the targeted depth forms a recessed surface of the placeholder material that is parallel with an upper surface of the semiconductor substrate prior to removing the semiconductor substrate.

16. The method of claim 14, wherein the targeted depth forms a recessed surface of the placeholder material that is above an upper surface of the semiconductor substrate prior to removing the semiconductor substrate.

17. The method of claim 8, wherein forming the first source/drain element and the second source/drain element includes epitaxially growing the first source/drain element from the deep trench source/drain placeholder material and epitaxially growing the second source/drain element from the source/drain placeholder material.

18. The method of claim 8, wherein the semiconductor substrate includes an etch stop layer positioned between a lower base portion of the semiconductor substrate and an upper base portion of the semiconductor substrate.

19. The method of claim 18, wherein removing the base of the semiconductor substrate comprises etching the upper base portion of the semiconductor substrate until stopping on the etch stop layer.

20. The method of claim 19, further comprising removing the etch stop layer and the lower base portion of the semiconductor substrate to expose the deep trench source/drain placeholder material and the source/drain placeholder material prior to modifying the deep trench source/drain placeholder material and the source/drain placeholder material.
